(19) United States
(12) Patent Application Publication
(10) Pub. No.: US 2008/0047740 A1
(43) Pub. Date: Feb. 28, 2008

(54) Circuit Board Assembly Having Passive Component and Stack Structure Thereof

(75) Inventors: Chung-Cheng Lien, Hsin-Chu (TW); Chia-Wei Chang, Hsin-Chu (TW)

Correspondence Address: SAWYER LAW GROUP LLP, P O BOX 51418, PALO ALTO, CA, 94303, US

(73) Assignee: PHOENIX PRECISION TECHNOLOGY CORPORATION, Hsin-Chu (TW)

(21) Appl. No.: 11/829,540

(22) Filed: Jul. 27, 2007

(30) Foreign Application Priority Data
Jul. 28, 2006 (TW) 095127692

(51) Int. Cl. H05K 1/09; H05K 1/16; H05K 1/18

(52) U.S. Cl. 174/256; 174/260; 361/761

(57) ABSTRACT

A circuit board assembly having at least a passive component and a stack structure of the circuit board are disclosed, including: a carrier board formed with a through opening for receiving a semiconductor component having an active surface on which electrode pads are formed; a dielectric layer formed on the carrier board and the semiconductor component and formed with openings to expose the electrode pads; a circuit layer formed on the dielectric layer and having conductive structures formed in the openings of the dielectric layer for electrically connecting the electrode pads, and a plurality of lands for mounting at least one passive component electrically connected to the circuit layer; and a circuit build-up structure formed on the dielectric layer, the circuit layer and the passive component, with conductive structures formed for electrically connecting the circuit layer.

### BACKGROUND OF THE INVENTION

1. Field of the Invention

The present invention relates generally to a circuit board structure having passive component and stack structure thereof, and more particularly to a circuit board structure integrated with semiconductor component and passive component, and stack structure thereof.

2. Description of Related Art

For consequent reduction in size of electronic components, much more semiconductor components having different functions are required to be embedded in a circuit board. To meet the requirement, a chip carrier of a semiconductor package such as a substrate or a leadframe must be mounted and electrically connected with at least two semiconductor chips, wherein the semiconductor chips are stack mounted on the chip carrier and electrically connected to the chip carrier by solder wires.

FIG. 1 is a sectional diagram of a multi-chip semiconductor package 2 disclosed by U.S. Pat. No. 5,323,060. As shown in FIG. 1, a first semiconductor chip 22a is mounted on a circuit board 21 and electrically connected with the circuit board 21 by first solder wires 23a. A second semiconductor chip 22b is then stack mounted on the first semiconductor chip 22a, interposed with an adhesive layer 24. The adhesive layer is generally made of an epoxy or a tape. The second semiconductor chip 22b is electrically connected with the circuit board 21 by second solder wires 23b. However, in such a package, the wire bonding process for the first semiconductor chip 22a must be performed before stacking of the second semiconductor chip 22b. That is, die bonding process and wire bonding process for each layer semiconductor chip must be separately performed, which is accordingly rather complicated. Further, as the first semiconductor chip 22a, the adhesive layer 24 and the second semiconductor chip 22b are stack mounted on the circuit board 21, to prevent the second semiconductor chip 22b from contacting the first solder wires 23a, the adhesive layer 24 should have a thickness which makes the adhesive layer 24 higher than arcs of the first solder wires 23a, as a result, the whole thickness of the multi-chip semiconductor package 2 is increased, and thinning of the semiconductor package is difficult to be realized. Meanwhile, as evenness of the adhesive layer 24 is difficult to control, it may occur that the second semiconductor chip 22b contacts the first solder wires 23a or the first solder wires 23a contacts the second solder wires 23b, thus resulting in problems such as short circuits.

In order to improve functionality of electronic products and decrease height of electronic products, much more attention is paid on techniques that embed semiconductor components such as active components or passive components in carriers. FIG. 2 is a conventional structural diagram of a carrier board with a semiconductor component embedded therein. As shown in FIG. 2, at least one opening 301 is formed in a carrier board 30. A semiconductor component 31 having an active surface 31a is received in the opening 301 of the carrier board 30, wherein a plurality of electrode pads 312 is formed on the active surface 31a of the semiconductor component 31. A dielectric layer 32 is further formed on the upper surface of the carrier board 30 and the active surface 31a of the semiconductor component 31, and a circuit layer 33 is formed on the dielectric layer 32. The circuit layer 33 has a plurality of conductive structures 331 for electrically connecting the electrode pads 312 of the semiconductor component 31. Through this build-up method, a multi-layer circuit board can be obtained.

In the above-described fabrication process, as only one semiconductor component 31 is embedded in the carrier board 30, electricity function of the carrier board 30 is limited. To increase the electricity function of the carrier board 30, the number of the semiconductor components 31 must be increased. Thus, a plurality of openings 301 should be formed on the carrier board 30. However, the limited size of the carrier board 30 restricts the enhancement and development of the electricity function of the carrier board 30.

Therefore, how to embed a semiconductor component in a circuit board and meanwhile strengthen its electricity demand and function so as to improve electricity function of the semiconductor package and meanwhile reduce size of the semiconductor package has become critical.

### SUMMARY OF THE INVENTION

According to the above drawbacks, an objective of the present invention is to provide a circuit board structure having passive component and stack structure thereof so as to decrease electricity transmission path.

Another objective of the present invention is to provide a circuit board structure having passive component and stack structure thereof, through which space of carrier board can be efficiently utilized so as to reduce the module size.

In order to attain the above and other objectives, the present invention provides a circuit board assembly having at least a semiconductor component, comprising: a carrier board formed with at least a through opening for receiving a semiconductor component having an active surface on which a plurality of electrode pads are formed; a dielectric layer formed on the carrier board and the active surface of the semiconductor component, and having a plurality of openings for exposing the electrode pads of the semiconductor component; a circuit layer formed on the dielectric layer and formed with a plurality of conductive structures in the openings of the dielectric layer for electrically connecting the electrode pads of the semiconductor component, the circuit layer further having a plurality of lands; at least a passive component mounted on the lands for electrically connecting the circuit layer; and a circuit build-up structure formed on the dielectric layer, the circuit layer and the passive component, the circuit build-up structure having a plurality of conductive structures for electrically connecting the circuit layer.

In the above structure, an adhesive layer is formed on the carrier board that is opposite to the active surface of the semiconductor component, and the adhesive layer is used to fill in gaps in the opening between the semiconductor component and the carrier board for securing in position the semiconductor component in the opening. The carrier board can be a metal board, a dielectric board or a circuit board having circuits. The semiconductor component is an active component and the passive component can be one of a resistor, a capacitor and an inductor.

Preferably, the circuit build-up structure comprises at least a dielectric layer, a circuit layer stacked on the dielectric layer and a plurality of conductive structures formed in the dielectric layer for electrically connecting the circuit layer with the semiconductor component. In addition, a solder mask layer is formed on the circuit build-up structure, and the solder mask layer has a plurality of openings for exposing the electrically connecting pads of the circuit build-up structure.

The present invention further provides a stack structure of a circuit board assembly having a passive component, which comprises; at least two carrier boards, each having at least a through opening and a semiconductor component having an active surface and a non-active surface opposed to the active surface received in the through opening, and wherein the two carrier boards are laminated together by an adhesive layer in such a manner that the semiconductor components received in the through openings are non-active surface-to-non-active surface attached; dielectric layers formed on the carrier boards and the active surfaces of the semiconductor components and having a plurality of openings for exposing the electrode pads of the semiconductor components; circuit layers formed on the dielectric layers and having a plurality of conductive structures formed in the openings of the dielectric layers for electrically connecting the electrode pads of the semiconductor components, the circuit layers having a plurality of lands; at least a passive component disposed on the lands of each circuit layer for electrically connecting the circuit layer; and a plurality of circuit build-up structures respectively formed on the dielectric layers and the passive components and having a plurality of conductive structures formed for electrically connecting the corresponding circuit layers.

The stack structure further comprises at least one plated through hole penetrating the two carrier boards and dielectric layers for electrically connecting the circuit layers of the carrier boards.

In the present invention, the carrier board is embedded with a semiconductor component and integrated with a passive component. Accordingly, the electricity function and the transmission efficiency between electronic components are enhanced. Meanwhile, a stack structure can be obtained by integrating carrier boards with an adhesive layer. Thus, the carrier board space can be efficiently utilized and the module size can be reduced.

### BRIEF DESCRIPTION OF DRAWINGS

FIG. 1 is a sectional diagram of a semiconductor package structure with several chips stacked therein.

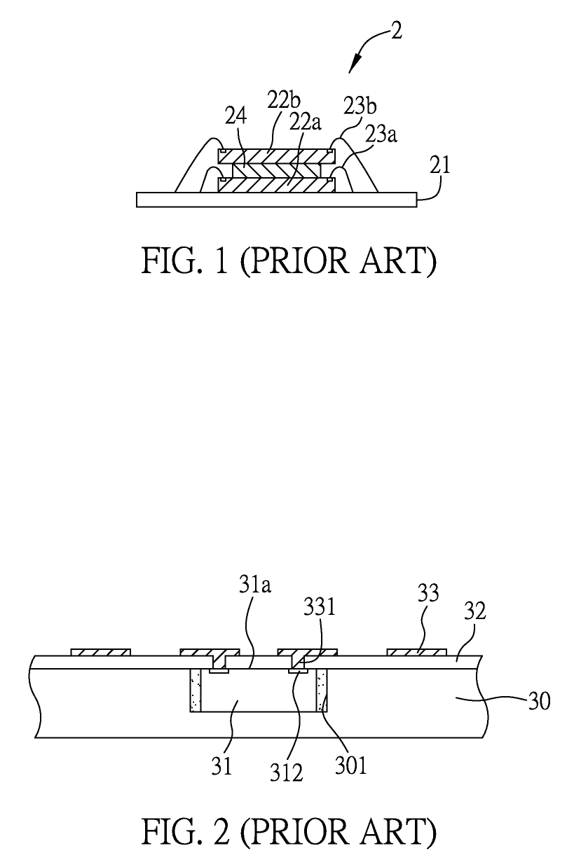

FIG. 2 is a diagram of a conventional circuit board structure with semiconductor component embedded therein;

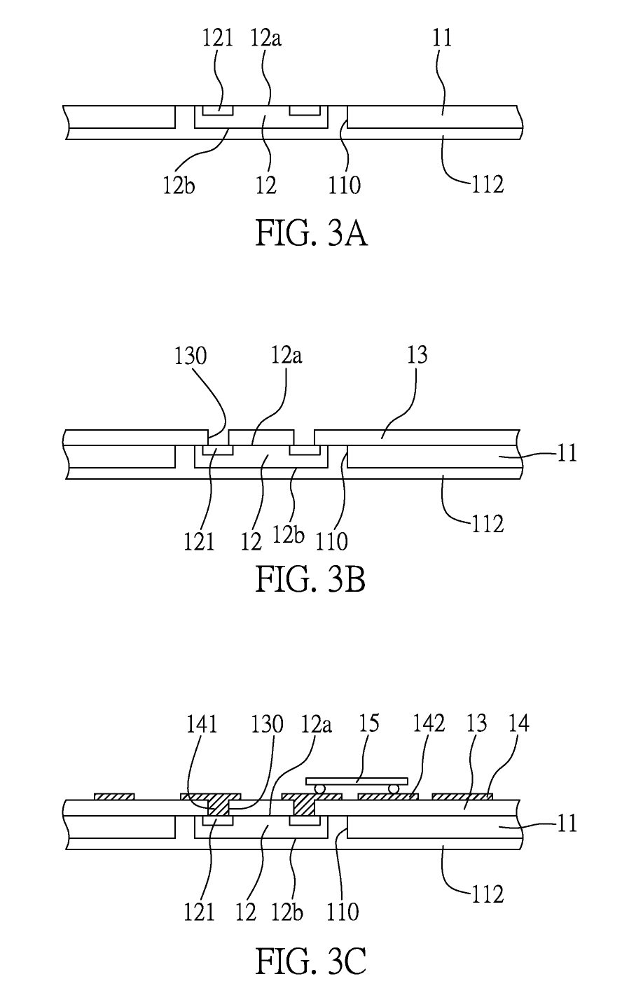

FIGS. 3A to 3D are sectional diagrams of a circuit board structure having passive component according to a first embodiment of the present invention; and

FIG. 4 is a sectional diagram of a circuit board structure having passive component according to a second embodiment of the present invention.

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification. The present invention can also be performed or applied by other different embodiments. The details of the specification may be on the basis of different points and applications, and numerous modifications and variations can be made without departing from the spirit of the present invention.

### First Embodiment

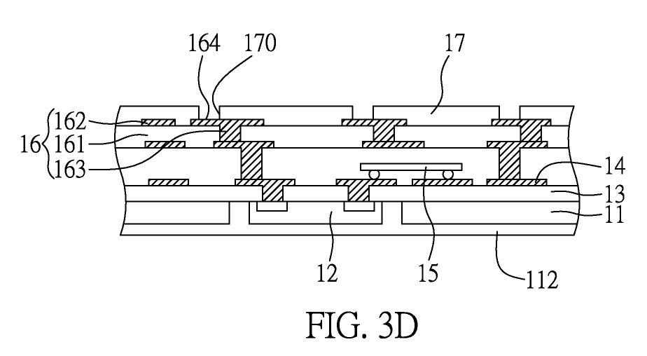

FIGS. 3A to 3D show a fabrication process of a circuit board structure having a passive component according to a first embodiment of the present invention.

As shown in FIG. 3A, a carrier board 11 formed with at least one through opening 110 is provided. The carrier board 11 may be a metal board, a dielectric board, or a circuit board having circuits thereon. A semiconductor component 12 having an active surface 12a is received in the through opening 110, wherein the active surface 12a of the semiconductor component 12 has a plurality of electrode pads 121 formed thereon. The semiconductor component 12 can be an active component such as a CPU, a DRAM, a SRAM or a SDRAM. An adhesive layer 112 is formed on one surface of the carrier board 11 that is opposite to the active surface 12a of the semiconductor component 12, and the adhesive layer 112 is used to fill in gaps between the opening 110 and the semiconductor component 12 for securing in position the semiconductor component 12 in the opening.

Referring to FIG. 3B, a dielectric layer 13 is formed on the carrier board 11 and the active surface 12a of the semiconductor component 12, and a plurality of openings 130 is formed in the dielectric layer 13 for exposing the electrode pads 121 of the semiconductor component 12. The dielectric layer 13 may be made of an epoxy resin, polyimide, cyanate ester, glass fiber, bismaleimide triazine (BT) or glass fiber-epoxy resin composites.

Referring to FIG. 3C, a circuit layer 14 is formed on the dielectric layer 13 and a plurality of conductive structures 141 are formed in the openings 130 of the dielectric layer 13 for electrically connecting the electrode pads 121 of the semiconductor component 12. In addition, the circuit layer 14 has a plurality of lands 142 to which at least one passive component 15 can be mounted such that the passive component 15 can be electrically connected with the circuit layer 14 through the lands 142. The passive component can be such as a capacitor, a resistor or an inductor.

The resistor may be formed by dispersing silver powder or carbon particles in resin, or dispersing RuO₂ and glass particles in a binder and then coating and curing, or filling such as Ni—Cr, Ni—P, Ni—Sn, Cr—Al, or TaN alloys in the passive component region. The capacitor is a high dielectric layer having big dielectric constant, which may be made of a high polymer material, a ceramic material, high polymer with dispersed ceramic particles or the like, such as barium-titanate, lead-zirconate-titanate, amorphous hydrogenated carbon or powders thereof dispersed in a binder.

Referring to FIG. 3D, a circuit build-up structure 16 is formed on the dielectric layer 13, the circuit layer 14 and the passive component 15. The circuit build-up structure 16 comprises a dielectric layer 161, a circuit layer 162 stacked on the dielectric layer 161, and a plurality of conductive structures 163 formed in the dielectric layer 161 and electrically connected with the circuit layer 14. Moreover, a plurality of electrically connecting pads 164 are formed on the circuit build-up structure 16. Further, a solder mask layer 17 is formed on the circuit build-up structure 16, and the solder mask layer 17 is formed with a plurality of openings 170 for exposing the electrically connecting pads 164 of the circuit build-up structure 16. Thus, the electricity function of the circuit board is enhanced through the circuit build-up structure 16.

Through the above-described fabrication method, the present invention further provides a circuit board assembly having at least a semiconductor component, which comprises: a carrier board 11 having at least one through opening 110 for receiving a semiconductor component 12 having an active surface 12a on which a plurality of electrode pads 121 are formed; a dielectric layer 13 formed on the carrier board 11 and the active surface 12a of the semiconductor component 12, and having a plurality of openings 130 for exposing the electrode pads 121 of the semiconductor component 12; a circuit layer 14 formed on the dielectric layer 13 and with a plurality of conductive structures 141 in the openings 130 of the dielectric layer 13 for electrically connecting the electrode pads 121 of the semiconductor component 12, in addition, the circuit layer 14 further has a plurality of lands 142; and at least one passive component 15 mounted on the lands 142 for electrically connecting the circuit layer 14.

As the passive component 15 is mounted on the lands 142 of the circuit layer 14, in combination with the semiconductor component 12 embedded in the opening 110 of the carrier board 11, the electricity function of the circuit board is improved and the semiconductor package size is decreased.

### Second Embodiment

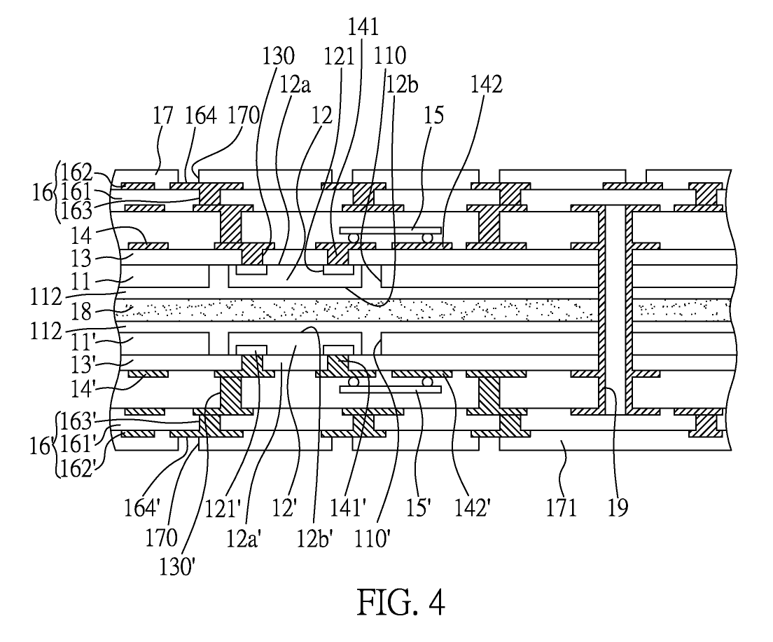

FIG. 4 shows a stack structure of a circuit board assembly having at least a passive component according to a second embodiment of the present invention. As shown in FIG. 4, the stack structure of the circuit board assembly comprises: at least two carrier boards 11, 11′ each having a through opening 110,110′ respectively for receiving semiconductor components 12, 12′ in the openings 110,110′, the semiconductor components 12, 12′ respectively having active surfaces 12a, 12a′ and non-active surfaces 12b, 12b′ and the active surfaces 12a, 12a′ respectively have a plurality of electrode pads 121,121′, the two carrier boards 11, 11′ as the non-active surfaces 12b, 12b′ of the semiconductor components 12, 12′ and the non-active surfaces 12b, 12b′ of the semiconductor components 12, 12′ are combined together by an adhesive layer 18; dielectric layers 13, 13′ respectively formed on the active surfaces 12a, 12a′ of the semiconductor components 12, 12′ as well as surfaces of the carrier boards 11, 11′ as the active surfaces 12a, 12a′, the dielectric layers 13, 13′ respectively having openings 130, 130′ for exposing the electrode pads 121, 121′ of the semiconductor components 12, 12′; circuit layers 14, 14′ respectively formed on the dielectric layers 13, 13′, wherein the circuit layers 14, 14′ have a plurality of conductive structures 141, 141′ respectively formed in the openings 130, 130′ of the dielectric layers 13, 13′ for electrically connecting the electrode pads 121, 121′ of the semiconductor components 12, 12′, the circuit layers 14, 14′ respectively have a plurality of lands 142, 142′ to which passive components 15, 15′ can be mounted and electrically connected with the circuit layers 14, 14′; circuit build-up structures 16,16′ formed on surfaces of the dielectric layers 13,13′, circuit layers 14, 14′ and passive components 15,15′, the circuit build-up structures 16,16′ having a plurality of conductive structures 163, 163′ formed for electrically connecting the circuit layers 14, 14′.

Through the above-described structure, two carrier board structure with the semiconductor components 12, 12′ embedded therein and mounted with the passive components 15,15′ are integrated together through the adhesive layer 18, thereby improving the electricity function.

The above-described structure can further comprise at least a plated through hole 19 penetrating through the carrier boards 11, 11′ and the dielectric layers 13, 13′ and electrically connecting the two circuit layers 14, 14′. The circuit build-up structures 16,16′ comprise dielectric layers 161, 161′, circuit layers 162, 162′ stacked on the circuit layers 161, 161′, and conductive structures 163, 163′ formed in the dielectric layers 161,161′. A plurality of electrically connecting pads 164, 164′ are formed on surfaces of the circuit build-up structures 16, 16′ and solder mask layers 17, 17′ are formed on the surfaces of the circuit build-up structures 16, 16′. A plurality of openings 170, 170′ is formed in the solder mask layers 17, 17′ for exposing the electrically connecting pads 164, 164′ of the circuit build-up structures 16, 16′.

Since the two carrier boards 11, 11′ with the semiconductor components 12, 12′ embedded therein and mounted with the passive components 15,15′ are electrically connected together through the plated through hole 19 and the circuit build-up structures 16,16′ are further formed on the two carrier boards 11, 11′, electricity connecting function of the carrier boards are enhanced.

The carrier boards 11, 11′ can be metal board, dielectric boards or circuit boards having circuits. The semiconductor components 12, 12′ can be active components or passive components such as resistors, capacitors, or inductors.

The present invention embeds a semiconductor component in a carrier board and disposes a passive component to the carrier board so as to obtain a circuit board structure. Further, circuit board structures can be integrated together to form a stack structure. Thus, the carrier board space can be efficiently utilized and the module size can be reduced. The structure can further be varied according to practical needs.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A circuit board assembly having at least a passive component, comprising:
a carrier board having at least a through opening for receiving a semiconductor component having an active surface on which a plurality of electrode pads are formed;
a dielectric layer formed on the carrier board and the active surface of the semiconductor component, and having a plurality of openings for exposing the electrode pads of the semiconductor component;
a circuit layer formed on the dielectric layer and formed with a plurality of conductive structures in the openings of the dielectric layer for electrically connecting the electrode pads of the semiconductor component, the circuit layer further having a plurality of lands;
at least a passive component mounted on the lands for electrically connecting the circuit layer; and
a circuit build-up structure formed on the dielectric layer, the circuit layer and the passive component, the circuit build-up structure having a plurality of conductive structures for electrically connecting the circuit layer.

2. The circuit board assembly of claim 1, wherein an adhesive layer is formed on the carrier board that is opposite to the active surface of the semiconductor component, and the adhesive layer is filled in gaps in the opening between the semiconductor component and the carrier board for securing in position the semiconductor component in the opening.

3. The circuit board assembly of claim 1, wherein the carrier board is one of a metal board, a dielectric board and a circuit board having circuits.

4. The circuit board assembly of claim 1, wherein the semiconductor component is an active component.

5. The circuit board assembly of claim 1, wherein a plurality of electrically connecting pads are formed on surface of the circuit build-up structure.

6. The circuit board assembly of claim 5, further comprising a solder mask layer formed on the circuit build-up structure, allowing the solder mask layer to be formed with a plurality of openings for exposing the electrically connecting pads of the circuit build-up structure.

7. The circuit board assembly of claim 1, wherein the circuit build-up structure comprises a dielectric layer, a circuit layer stacked on the dielectric layer and conductive structures formed in the dielectric layer.

8. The circuit board assembly of claim 1, wherein the passive component is one of a resistor, a capacitor and an inductor.

9. A stack structure of a circuit board assembly having at least a passive component, comprising;
at least two carrier boards, each formed with at least a through opening and a semiconductor component having an active surface and a non-active surface opposed to the active surface received in the through opening, wherein the active surface of the semiconductor component has a plurality of electrode pads and wherein the two carrier boards are laminated together by an adhesive layer in such a manner that the semiconductor components received in the through openings are non-active surface-to-non-active surface attached;
dielectric layers formed on the carrier boards and the active surfaces of the semiconductor components, and having a plurality of openings for exposing the electrode pads of the semiconductor components;
circuit layers formed on the dielectric layers and having a plurality of conductive structures formed in the openings of the dielectric layers for electrically connecting the electrode pads of the semiconductor components, the circuit layers further formed with a plurality of lands;
at least a passive component disposed on the lands of each circuit layer for electrically connecting the circuit layer; and
circuit build-up structures respectively formed on the dielectric layers, the circuit layers and the passive components, and having a plurality of conductive structures formed for electrically connecting the corresponding circuit layers.

10. The stack structure of claim 9, wherein an adhesive layer is formed on each carrier board that is opposite to the active surface of the semiconductor component, and the adhesive layer is used to fill in gaps between the semiconductor component and the carrier board for securing in position the semiconductor component received in the through opening.

11. The stack structure of claim 9, wherein the carrier boards are made of one of a metal board, a dielectric board and a circuit board having circuits.

12. The stack structure of claim 9, wherein the semiconductor component is an active components.

13. The stack structure of claim 9, wherein a plurality of electrically connecting pads are formed on the circuit build-up structures.

14. The stack structure of claim 13, further comprising solder mask layers formed on the circuit build-up structures and having a plurality of openings for exposing the electrically connecting pads of the circuit build-up structures.

15. The stack structure of claim 9, wherein each circuit build-up structure comprises a dielectric layer, a circuit layer stacked on the dielectric layer and conductive structures formed in the dielectric layer.

16. The stack structure of claim 9, wherein the passive component is one of a resistor, a capacitor and an inductor.
